(19) United States
(12) Patent Application Publication
(10) Pub. No.: US 2025/0096124 A1
(43) Pub. Date: Mar. 20, 2025

(54) HORIZONTAL ANTIFUSE

(71) Applicant: INTERNATIONAL BUSINESS MACHINES CORPORATION, ARMONK, NY (US)

(72) Inventors: Ashim Dutta, Clifton Park, NY (US); Chih-Chao Yang, Glenmont, NY (US); Shravana Kumar Katakam, Lehi, UT (US)

(21) Appl. No.: 18/469,649

(22) Filed: Sep. 19, 2023

(51) Int. Cl. H01L 23/525

(52) U.S. Cl. CPC H01L 23/5252

(57) ABSTRACT

An antifuse structure including a first fuse conductor, a second fuse conductor in the same metallization level as the second fuse conductor, and a tapered fuse dielectric between and separating the first fuse conductor from the second fuse conductor.

### BACKGROUND

The present invention generally relates to semiconductor structures, and more particularly to a horizontal antifuse structure.

Integrated circuit processing can be generally divided into front end of the line (FEOL), middle of the line (MOL) and back end of the line (BEOL) processes. The FEOL and MOL processing will generally form many layers of logical and functional devices. By way of example, the typical FEOL processes include wafer preparation, isolation, well formation, gate patterning, spacer, extension and source/drain implantation, silicide formation, and dual stress liner formation. The MOL is mainly gate contact formation. Layers of interconnections are formed above these logical and functional layers during the BEOL processing to complete the integrated circuit structure. As such, BEOL processing generally involves the formation of insulators and conductive wiring. The industry has typically used copper as the conductive metal for the interconnect structures most often using a dual damascene process to form a metal line/via interconnect structure.

A fuse is a structure that is normally “on” meaning that current is flowing, but once “programmed” it is “off” meaning that current does not flow. In a fuse, programming means applying a suitable voltage so that the fuse “blows” to create an open circuit or high resistance state. An antifuse is a structure that is normally “off” meaning that no current flows, but once “programmed” it is “on” meaning that current does flow. In an antifuse, programming means applying a suitable voltage to two electrodes and forming a conductive link between them to close the circuit.

In integrated circuitry memory devices, fuses and antifuses can be used for activating redundancy in memory chips and for programming functions and codes in logic chips. Specifically, dynamic random access memory (DRAM) and static random access memory (SRAM) may use fuses and antifuses for such purposes. In addition, fuses and antifuses can also be used to prevent decreased chip yield caused by random defects generated in the manufacturing process. Moreover, fuses and anti-fuses provide for future customization of a standardized chip design. For example, fuses and anti-fuses may provide for a variety of voltage options, packaging pin out options, or any other options desired by the manufacturer to be employed prior to the final processing. These customization possibilities make it easier to use one basic design for several different end products and help increase chip yield.

### SUMMARY

According to an embodiment of the present invention, an antifuse structure is provided. The antifuse structure may include a first fuse conductor, a second fuse conductor in the same metallization level as the second fuse conductor, and a tapered fuse dielectric between and separating the first fuse conductor from the second fuse conductor.

According to another embodiment of the present invention, an antifuse structure is provided. The antifuse structure may include a first fuse conductor, a second fuse conductor in the same metallization level as the second fuse conductor, and a tapered fuse dielectric between and separating the first fuse conductor from the second fuse conductor, an uppermost surface of the fuse dielectric is substantially flush with an uppermost surface of each of the first and second fuse conductors.

According to another embodiment of the present invention, an antifuse structure is provided. The antifuse structure may include a first fuse conductor, a second fuse conductor, bottommost surfaces of each of the first and second fuse conductors are substantially flush with one another, and a tapered fuse dielectric between and separating the first fuse conductor from the second fuse conductor, an uppermost surface of the fuse dielectric is substantially flush with an uppermost surface of each of the first and second fuse conductors.

### BRIEF DESCRIPTION OF THE DRAWINGS

The following detailed description, given by way of example and not intended to limit the invention solely thereto, will best be appreciated in conjunction with the accompanying drawings, in which:

FIG. 1 illustrates a cross-sectional view of the semiconductor structure during an intermediate step of a method of fabricating an interconnect structure according to an exemplary embodiment;

FIG. 2 illustrates a cross-sectional view of the semiconductor structure after forming a conductive layer according to an exemplary embodiment;

FIG. 3 illustrates a cross-sectional view of the semiconductor structure after removing portions of the conductive layer according to an exemplary embodiment;

FIG. 4 illustrates a cross-sectional view of the semiconductor structure after forming a second dielectric layer according to an exemplary embodiment;

FIG. 5 illustrates a cross-sectional view of the semiconductor structure after removing portions of the second dielectric layer according to an exemplary embodiment;

FIG. 6 illustrates a cross-sectional view of the semiconductor structure after forming fuse contacts according to an exemplary embodiment;

FIG. 7 illustrates a cross-sectional view of the semiconductor structure after removing different portions of the second dielectric layer according to an exemplary embodiment;

FIG. 8 illustrates a cross-sectional view of the semiconductor structure after forming a fuse dielectric according to an exemplary embodiment;

FIG. 8a illustrates a cross-sectional view of the semiconductor structure after programming the antifuse structure according to an exemplary embodiment;

FIG. 9 illustrates a cross-sectional view of the semiconductor structure after removing different portions of the second dielectric layer according to an alternative exemplary embodiment;

FIG. 10 illustrates a cross-sectional view of the semiconductor structure after forming a fuse dielectric according to the alternative exemplary embodiment; and

FIG. 10a illustrates a cross-sectional view of the semiconductor structure after programming the antifuse structure according to the alternative exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Antifuses become difficult to fabricate when interconnect dimensions scales down. Some antifuse structures can be fabricated by placing metal islands between metal wires embedded in a dielectric material. Other antifuse structures can be fabricated by placing a relatively high resistance metal between metal wires. Such antifuse structures are difficult to fabricate as the spacing between the metal wires becomes sub-15 nm. Additionally, antifuses are typically relatively bulky and take up a valuable space in an integrated circuit design. Further, bulky antifuse structures reduce the amount of available space for more important interconnect structures, for example, metal wires, and other circuit components in the circuit.

The present invention generally relates to semiconductor structures, and more particularly to a horizontal antifuse structure. More specifically, the horizontal antifuse structures disclosed herein is contained within a single metallization level and includes two fuse conductors separated by a tapered fuse dielectric. Exemplary embodiments of taper antifuse structures are described in detail below by referring to the accompanying drawings in FIGS. 1 to 10. Those skilled in the art will readily appreciate that the detailed description given herein with respect to these figures is for explanatory purposes as the invention extends beyond these limited embodiments.

Referring now to FIG. 1 a demonstrative illustration of a structure 100 is shown during an intermediate step of a method of fabricating an antifuse structure according to an embodiment of the invention.

The structure 100 may include one or more back-end-of-line metallization levels, and more specifically, a metallization level 102. According to at least one embodiment, the metallization level 102 may include a via level or a metal level, as both are well known to persons having ordinary skill in the art. Although the metallization levels disclosed herein would typically be part of the back-end-of-line, embodiments of the present invention explicitly contemplate other locations and arrangements, such as, for example, middle-of-line, wafer backside, wafer frontside, or other known metallization regions. In all cases, the horizontal antifuse structures described herein, and represented by the structure 100, will be integral to the electrical wiring system of a final device or package.

According to at least one embodiment, the metallization level 102 is a typical back-end-of-line level and includes a network of conductive lines or vias embedded in a first dielectric layer 104. The network of conductive lines or vias form the “wiring” or electrical connections to underlying transistors and devices (not shown). The conductive lines may alternatively be referred to as metal lines, traces, or metal traces.

According to embodiments of the present invention, the first dielectric layer 104 may be provided according to known techniques. The first dielectric layer 104 may be made from suitable interlevel dielectric materials such as silicon based low-k dielectrics, or porous dielectrics. For example, the first dielectric layer 104 may be made from organic polymer low-k dielectrics and SiCOH-based low-k dielectrics (such as SiCOH, SiCNOH).

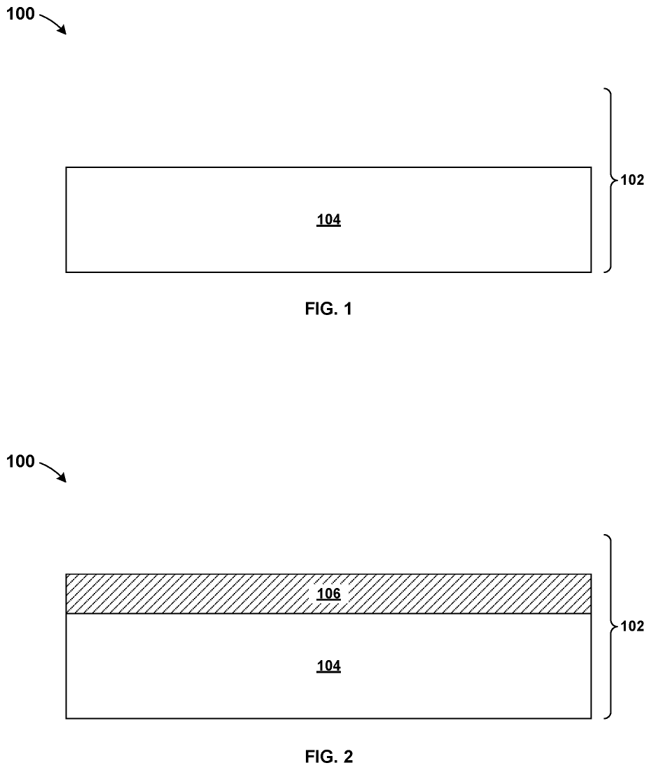

Referring now to FIG. 2, the structure 100 is shown after forming a conductive layer 106 in accordance with an embodiment of the present invention.

The conductive layer 106 is conformally deposited on exposed surfaces of the structure 100 according to known techniques. As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

According to embodiments of the present invention, the conductive layer 106 may include any suitable conductive material capable of conducting sufficient current of any typical semiconductor circuit having an antifuse structure. In an embodiment, the conductive layer 106 may include copper, tantalum nitride, titanium nitride, tungsten nitride, or some combination thereof. In at least one embodiment, the conductive layer 106 may have a thickness, ranging from about 30 nm to about 50 nm. Typically, the conductive layer 106 may include a single layer; however, in other embodiments, it may include multiple layers of different conductive materials.

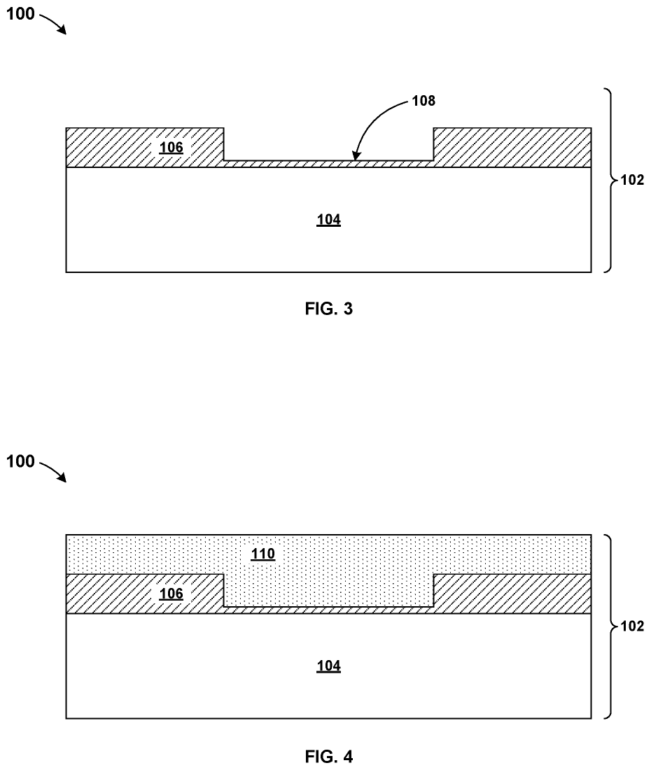

Referring now to FIG. 3, the structure 100 is shown after removing portions of the conductive layer 106 in accordance with an embodiment of the present invention.

An etching technique is applied to generally remove portions of the conductive layer 106 according to known techniques. Specifically, a mask (not shown) is formed directly on top of the conductive layer 106, and exposed portions of the conductive layer 106 are removed selective to the mask, as shown. A suitable directional etching technique is used to etch exposed portions of the conductive layer 106. Etching continues until exposed portions of the conductive layer 106 are reduced to a thin strip 108. For example, a vertical thickness of the thin strip 108 of the conductive layer 106 remaining after etching should range from about 1 nm to about 10 nm, with 5 nm being most typical. In all cases, it is critical that etching stops before exposing the first dielectric layer 104.

In some embodiments, the mask may include an oxide such as silicon oxide (SiO), a nitride such as silicon nitride (SiN), an oxynitride such as silicon oxynitride (SiON), combinations thereof, etc. In some embodiments, the mask is a silicon nitride such as Si₃N₄.

The object of this directional etching technique is to form the thin strip 108, as illustrated. Suitable directional etching techniques may include, but are not limited to: reactive ion etching (RIE), ion beam etching, plasma etching, or laser ablation. In an embodiment, a RIE technique using, for example, with or without including argon ion species, may be used to remove portions of the conductive layer 106.

Despite only a thin strip 108 is illustrated in FIG. 3, embodiments of the present invention explicitly contemplate configurations of the structure 100 which include multiple thin strips (108) arranged across a design. In such embodiments, the thin strips are located or positioned in regions intended for the horizontal antifuse structures described herein.

Referring now to FIG. 4, the structure 100 is shown after forming a second dielectric layer 110 in accordance with an embodiment of the present invention.

The second dielectric layer 110 is conformally deposited on exposed surfaces of the structure 100 according to known techniques. More specifically, the second dielectric layer 110 is deposited directly on exposed surfaces of the conductive layer 106 covering the thin strip 108, as illustrated. The second dielectric layer 110 will preferably cover an entirety of the conductive layer 106. For purposes of the present description, the second dielectric layer 110 is the same, or substantially similar, as the first dielectric layer 104 previously described. In an alternate embodiment, the second dielectric layer 110 is a different material than the first dielectric layer 104.

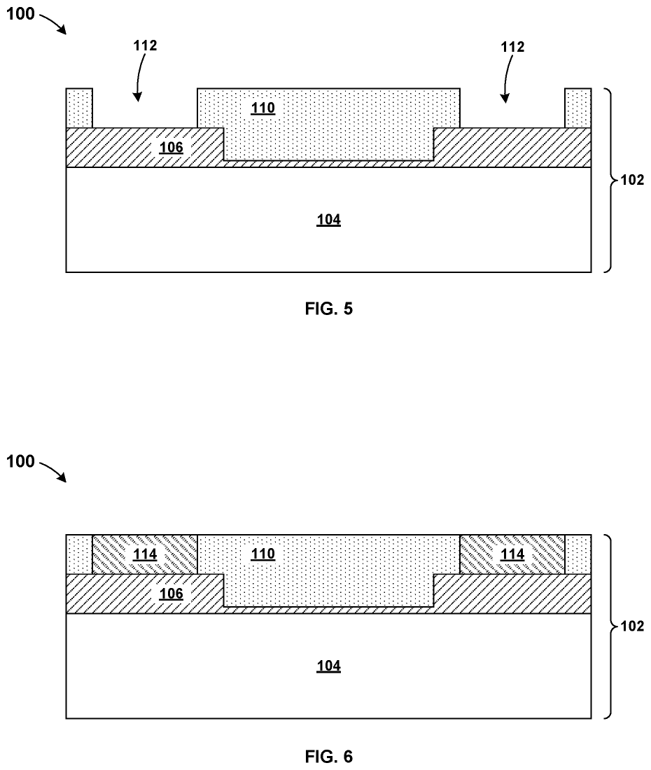

Referring now to FIG. 5, the structure 100 is shown after removing portions of the second dielectric layer 110 in accordance with an embodiment of the present invention.

An etching technique is applied to generally remove portions of the second dielectric layer 110 and form trenches 112 according to known techniques. Specifically, a mask (not shown) is formed directly on top of the second dielectric layer 110, and exposed portions of the second dielectric layer 110 are removed selective to the mask, as shown. A suitable directional etching technique is used to etch exposed portions of the second dielectric layer 110. Etching continues until uppermost surfaces of the conductive layer 106 are exposed, as illustrated. According to embodiments of the present invention, the thin strip 108 is not exposed during etching of the second dielectric layer 110.

In some embodiments, the mask may include an oxide such as silicon oxide (SiO), a nitride such as silicon nitride (SiN), an oxynitride such as silicon oxynitride (SiON), combinations thereof, etc. In some embodiments, the mask is a silicon nitride such as Si₃N₄.

The object of this directional etching technique is to form the trenches 112, as illustrated. Suitable directional etching techniques may include, but are not limited to: reactive ion etching (RIE), ion beam etching, plasma etching, or laser ablation. In an embodiment, a RIE technique using, for example, with or without including argon ion species, may be used to remove portions of the conductive layer 106.

Referring now to FIG. 6, the structure 100 is shown after forming fuse contacts 114 in accordance with an embodiment of the present invention.

The trenches 112 are filled with a conductive material to form the fuse contacts 114 according to known techniques. For example, according to typical damascene techniques, after the trenches 112 are formed in the second dielectric layer 110, they are subsequently filled with a conductive material thereby forming the fuse contacts 114. According to disclosed embodiments, the fuse contacts 114 can be individual conductive elements or integrated as part of a metal line or via. After deposition of the conductive material, a planarization technique such as, for example, chemical mechanical planarization (CMP) and/or grinding is applied to remove excess material according to known techniques. After polishing topmost surfaces of the second dielectric layer 110 are flush, or substantially flush, with topmost surfaces of the fuse contacts 114, as illustrated.

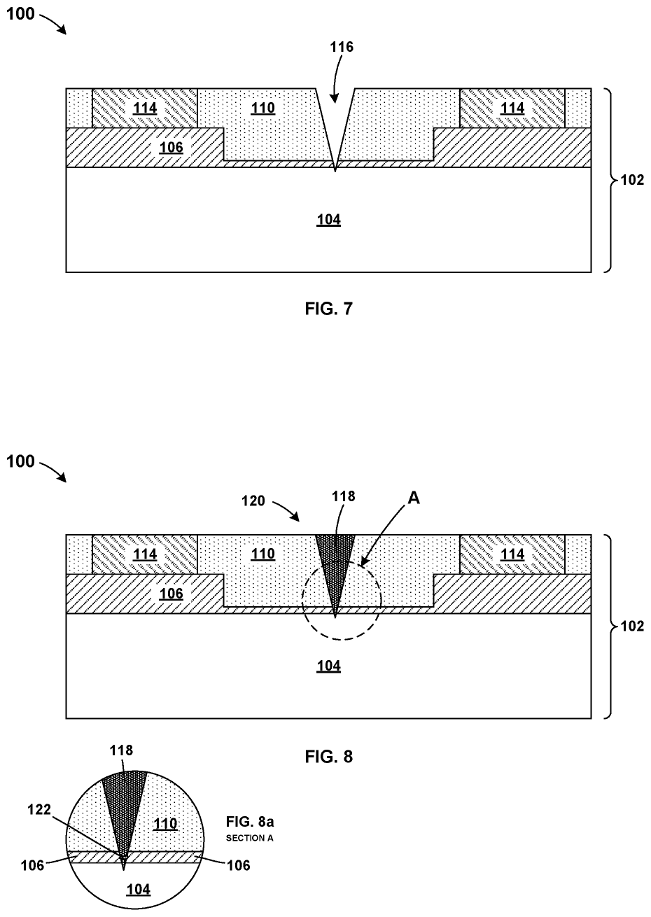

Referring now to FIG. 7, the structure 100 is shown after removing different portions of the second dielectric layer 110 in accordance with an embodiment of the present invention.

An etching technique is applied to generally remove portions of the second dielectric layer 110 and form a fuse trench 116 according to known techniques. Specifically, a mask (not shown) is formed directly on top of the second dielectric layer 110, and exposed portions of the second dielectric layer 110 are removed selective to the mask, as shown. A suitable directional etching technique is used to etch exposed portions of the second dielectric layer 110. Etching continues until the thin strip 108 is pierced and the first dielectric layer 104 is exposed. Said differently, etching must continue until the fuse trench 116 extends completely through the thin strip 108 dividing it into two opposite sections.

In some embodiments, the mask may include an oxide such as silicon oxide (SiO), a nitride such as silicon nitride (SiN), an oxynitride such as silicon oxynitride (SiON), combinations thereof, etc. In some embodiments, the mask is a silicon nitride such as Si₃N₄.

The object of this directional etching technique is to form the fuse trench 116, and more specifically, to form a small break separating the thin strip 108 as illustrated. This may be accomplished by carefully monitoring and controlling the chosen etching technique to create the fuse trench 116 having an inverted cone shape where the narrow end of the inverted cone pierces the thin strip 108. For example, suitable directional etching techniques may include, but are not limited to: ion etching or reactive ion etching (RIE). Furthermore, rotating the wafer during etching can be used to achieve the desired result. In a preferred embodiment, a lateral width of the break in the thin strip 108 created by the fuse trench 116 may be approximately 1 nm to approximately 10 nm. Adjusting the size of the fuse trench 116 by controlling the etching technique will ultimately affect the function of the resulting horizontal fuse, as described further below.

Referring now to FIG. 8, the structure 100 is shown after forming a fuse dielectric 118 in accordance with an embodiment of the present invention.

The fuse dielectric 118 is blanket deposited directly on exposed surfaces of the structure 100 according to known techniques. More specifically, the fuse dielectric 118 is deposited such that is completely fills the fuse trench 116, as illustrated. After deposition of the fuse dielectric 118, a planarization technique such as, for example, chemical mechanical planarization (CMP) and/or grinding is applied to remove excess material according to known techniques. After polishing topmost surfaces of the fuse dielectric 118 are flush, or substantially flush, with topmost surfaces of the second dielectric layer 110, as illustrated.

It is critical to the present invention that the fuse dielectric 118 is different than the second dielectric layer 110. More specifically, the fuse dielectric 118 is a dielectric material carefully selected for its dielectric breakdown properties. For example, according to embodiments of the present invention, the fuse dielectric 118 has a dielectric breakdown voltage less than the surrounding dielectrics; however, such is not necessary. Alternatively, the fuse dielectric 118 can be chosen based on maximum allowed programming voltage to be used to initiate breakdown. Low dielectric breakdown voltage will help lowering programming voltage.

Dielectric breakdown is the failure of an insulating material to prevent the flow of current under an applied electrical stress. The breakdown voltage is the voltage at which the failure occurs, and the material is no longer electrically insulating.

According to embodiments of the present invention, portions of the conductive layer 106 and the fuse contact 114 on either side of the fuse dielectric 118 may collectively be referred to as a fuse conductor. Finally, for purposes of the present description the opposite fuse conductors and the fuse dielectric 118 together form an antifuse structure 120.

Referring now to FIG. 8a, the structure 100 is shown after programming the antifuse structure 120 in accordance with an embodiment of the present invention. Specifically, FIG. 8a is a section view, section a, of FIG. 8.

The relatively small distance between the fuse conductors, specifically located in the thin strip 108, and the placement of the fuse dielectric 118 together create a “weak point” prone to dielectric breakdown. More specifically, dielectric breakdown during fuse programing creates a conductive link 122 between the opposite fuse conductors, as illustrated. The antifuse structure 120 can be programmed by applying a programming voltage to either of the fuse conductors and grounding the other. In the context of the present invention, either the programming voltage or the ground may be applied to either of the fuse conductors, and vice versa. Persons having ordinary skill in the art understand the structure 100 disclosed herein will be part of a larger integrated circuit and include additional metal layers, wiring, traces, vias which may also be involved in programming.

The programming voltage, which should be equal to or greater than the breakdown voltage of the fuse dielectric 118 may range from about 0.1 V to about 10 V, and have a current ranging from about 2 mA to about 10 mA. As a result, the fuse dielectric 118 no longer serves as an insulator, and conductive paths, for example the conductive link 122, are created within the fuse dielectric 118 between the fuse conductors, as illustrated. Even more specifically, the conductive link 122 forms in the tip, or narrowest portion of the inverted cone shape of the fuse dielectric 118. Alternatively, the fuse dielectric 118 may alternatively be referred to as a tapered fuse dielectric.

With continued reference to FIGS. 8 and 8a, in at least one example, the breakdown distance is about equal to the spacing between the two adjacent fuse conductors created by the fuse trench 116 (FIG. 7). However, programing is not solely dependent on the breakdown distance alone. As previously indicated above, programming of the antifuse structure 120 is caused by the dielectric breakdown of the fuse dielectric 118, and the dielectric material chosen for the fuse dielectric 118 is at least partly responsible for programming behavior of the antifuse structure 120. Even further, the dielectric breakdown down depends on defectivity, and the more area creates more defectivity and causes dielectric breakdown down sooner.

As illustrated in FIGS. 8 and 8a, the antifuse structure 120 has some distinctive and notable features. For example, the horizontal antifuse structure 120 has a smaller footprint than typical antifuse structures and can thus be implemented in higher density arrangements. Additionally, the fuse dielectrics can be individually tailored to achieve specific programing characteristics.

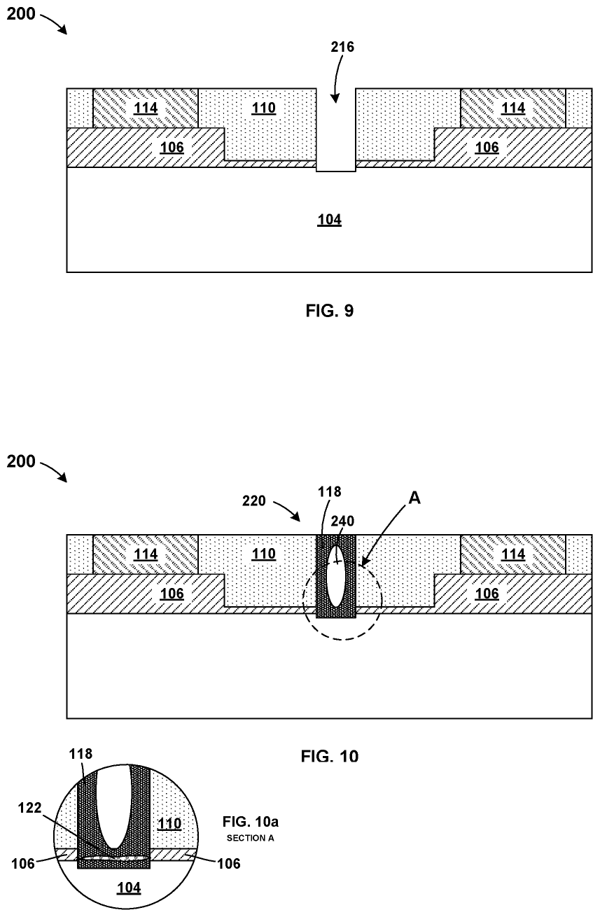

Referring now to FIGS. 9 and 10, a demonstrative illustration of a structure 200 is shown during intermediate steps of a method of fabricating an antifuse structure according to an alternative embodiment of the invention. Specifically, fabrication of the structure 200 described herein begins with the structure 100 of FIG. 6. As such, the structure 200 is substantially similar in all respects to the structure 100 except for the differences described immediately below.

Referring now to FIG. 9, the structure 200 is shown after removing different portions of the second dielectric layer 110 in accordance with an embodiment of the present invention.

An etching technique is applied to generally remove portions of the second dielectric layer 110 and form a fuse trench 216 according to known techniques. Specifically, a mask (not shown) is formed directly on top of the second dielectric layer 110, and exposed portions of the second dielectric layer 110 are removed selective to the mask, as shown. A suitable directional etching technique is used to etch exposed portions of the second dielectric layer 110. Etching continues until the thin strip 108 is pierced and the first dielectric layer 104 is exposed. Said differently, etching must continue until the fuse trench 216 extends completely through the thin strip 108 dividing it into two opposite sections.

In some embodiments, the mask may include an oxide such as silicon oxide (SiO), a nitride such as silicon nitride (SiN), an oxynitride such as silicon oxynitride (SiON), combinations thereof, etc. In some embodiments, the mask is a silicon nitride such as Si₃N₄.

The object of this directional etching technique is to form the fuse trench 216, and more specifically, to form a break separating the thin strip 108 as illustrated. Suitable directional etching techniques may include, but are not limited to: reactive ion etching (RIE), ion beam etching, plasma etching, or laser ablation. In an embodiment, a RIE technique using, for example, with or without including argon ion species, may be used to remove portions of the conductive layer 106. The fuse trench 116 of the structure 100 and the fuse trench 216 of the structure 200 have different shapes. Unlike the inverted cone shape of the fuse trench 116, the fuse trench 216 of the structure 200 has a more conventional square or rectangular shape. As such, a lateral width of the break in the thin strip 108 created by the fuse trench 216 may be approximately 10 nm to approximately 20 nm. Similar to the fuse trench 116, adjusting the size of the fuse trench 216 will also affect the function of the resulting horizontal fuse, as described further below.

Finally, for purposes of the present description the opposite fuse conductors and the fuse dielectric 118 of the structure 200 together form an antifuse structure 220.

Referring now to FIG. 10, the structure 200 is shown after forming the fuse dielectric 118 in accordance with an embodiment of the present invention. Like above, the fuse dielectric 118 is blanket deposited directly on exposed surfaces of the structure 200 and completely fills the fuse trench 216, as illustrated. Also like above, a planarization technique such as, for example, chemical mechanical planarization (CMP) and/or grinding is applied to remove excess fuse dielectric material according to known techniques. After polishing topmost surfaces of the fuse dielectric 118 are flush, or substantially flush, with topmost surfaces of the second dielectric layer 110, as illustrated. Because of the size and shape of the fuse trench 216 of the structure 200, there is a possibility for an air gap 240 to form in the fuse dielectric 118 during deposition. The air gap 240 is neither preferred or problematic; however, it does provide a structural signature or artifact.

Referring now to FIG. 10a, the structure 200 is shown after programming the antifuse structure 220 in accordance with an embodiment of the present invention. Specifically, FIG. 10a is a section view, section a, of FIG. 10. Programming the antifuse structure 220 of the structure 200 is substantially similar to the programming of the antifuse structure 120 of the structure 100 described above.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. An antifuse structure comprising:
a first fuse conductor;
a second fuse conductor in the same metallization level as the second fuse conductor; and
a tapered fuse dielectric between and separating the first fuse conductor from the second fuse conductor.

2. The antifuse structure according to claim 1, further comprising:
a first dielectric layer, wherein both the first and second fuse conductors are directly on the first dielectric layer; and
a second dielectric layer surrounding the tapered fuse dielectric.

3. The antifuse structure according to claim 1, wherein a lateral width of the tapered fuse dielectric measured at a topmost surface of the first and second fuse conductors is larger than a lateral width of the tapered fuse dielectric measured at a bottommost of the first and second fuse conductors.

4. The antifuse structure according to claim 1, wherein the tapered fuse dielectric extends beneath both the first fuse conductor and the second fuse conductor.

5. The antifuse structure according to claim 1, wherein each of the first and second fuse conductors comprise a first portion having a first height, a second portion having a second height and a third portion having a third height.

6. The antifuse structure according to claim 5, wherein the fuse dielectric directly contacts only the third portion of each of the first and second fuse conductors.

7. The antifuse structure according to claim 1, further comprising:
a conductive link in direct contact with and extending between the first fuse conductor and the second fuse conductor through the fuse dielectric.

8. An antifuse structure comprising:
a first fuse conductor;
a second fuse conductor in the same metallization level as the second fuse conductor; and
a tapered fuse dielectric between and separating the first fuse conductor from the second fuse conductor, wherein an uppermost surface of the fuse dielectric is substantially flush with an uppermost surface of each of the first and second fuse conductors.

9. The antifuse structure according to claim 8, further comprising:
a first dielectric layer, wherein both the first and second fuse conductors are directly on the first dielectric layer; and
a second dielectric layer surrounding the tapered fuse dielectric.

10. The antifuse structure according to claim 8, wherein a lateral width of the tapered fuse dielectric measured at a topmost surface of the first and second fuse conductors is larger than a lateral width of the tapered fuse dielectric measured at a bottommost of the first and second fuse conductors.

11. The antifuse structure according to claim 8, wherein the tapered fuse dielectric extends beneath both the first fuse conductor and the second fuse conductor.

12. The antifuse structure according to claim 8, wherein each of the first and second fuse conductors comprise a first portion having a first height, a second portion having a second height and a third portion having a third height.

13. The antifuse structure according to claim 12, wherein the fuse dielectric directly contacts only the third portion of each of the first and second fuse conductors.

14. The antifuse structure according to claim 8, further comprising:
a conductive link in direct contact with and extending between the first fuse conductor and the second fuse conductor through the fuse dielectric.

15. An antifuse structure comprising:
a first fuse conductor;
a second fuse conductor, wherein bottommost surfaces of each of the first and second fuse conductors are substantially flush with one another; and
a tapered fuse dielectric between and separating the first fuse conductor from the second fuse conductor, wherein an uppermost surface of the fuse dielectric is substantially flush with an uppermost surface of each of the first and second fuse conductors.

16. The antifuse structure according to claim 1, further comprising:
a first dielectric layer, wherein both the first and second fuse conductors are directly on the first dielectric layer; and
a second dielectric layer surrounding the tapered fuse dielectric.

17. The antifuse structure according to claim 1, wherein a lateral width of the tapered fuse dielectric measured at a topmost surface of the first and second fuse conductors is larger than a lateral width of the tapered fuse dielectric measured at a bottommost of the first and second fuse conductors.

18. The antifuse structure according to claim 1, wherein the tapered fuse dielectric extends beneath both the first fuse conductor and the second fuse conductor.

19. The antifuse structure according to claim 1, wherein each of the first and second fuse conductors comprise a first portion having a first height, a second portion having a second height and a third portion having a third height.

20. The antifuse structure according to claim 19, wherein the fuse dielectric directly contacts only the third portion of each of the first and second fuse conductors.
